(19) United States
(12) Patent Application Publication
(10) Pub. No.: US 2008/0017408 A1
(43) Pub. Date: Jan. 24, 2008

(54) Device With Mounted Electronic Parts, Method Of Producing The Same, Protection Circuit Module Of Secondary Battery, And Battery Package

(76) Inventors: Seiichi Morishita, Hyogo (JP); Hideki Yamada, Tottori (JP)

Correspondence Address: COOPER & DUNHAM, LLP, 1185 AVENUE OF THE AMERICAS, NEW YORK, NY, 10036, US

(21) Appl. No.: 11/661,901

(22) PCT Filed: Jun. 28, 2006
(86) PCT No.: PCT/JP06/13350

§ 371 Date: Jul. 23, 2007

(30) Foreign Application Priority Data
Jul. 4, 2005 (JP) 2005-194605

(51) Int. Cl. H05K 3/00; H05K 3/30

(52) U.S. Cl. 174/260; 320/134; 361/748; 429/123; 29/841

(57) ABSTRACT

A method of fabricating a device including plural electronic parts mounted on a circuit board with mounting areas for mounting the electronic parts being covered by a sealing resin is disclosed. The method prevents small air bubbles from entering into the sealing resin near the electronic parts. The method includes the steps of, before applying the sealing resin, applying an under-fill resin near the electronic parts with plural nozzles at the same time, and hardening the under-fill resin to form a taper-shaped structure around the electronic parts.

### TECHNICAL FIELD

The present invention relates to a device which has plural electronic parts mounted on a circuit board with the mounting areas for mounting the electronic parts being covered by a sealing resin, a method of fabricating the device, a protection circuit module of a secondary battery, and a battery package using the protection circuit module.

Here, the electronic parts may be thermistor elements (such as PTC elements), resistors, or condensers.

### BACKGROUND ART

Secondary batteries, which can be recharged repeatedly, are frequently used as batteries in various portable information processing devices. When using the secondary batteries, it is crucial to prevent performance degradation and reduce the size and cost of the secondary batteries, and enable the secondary batteries to supply power for a long term. In the related art, for example, in a lithium ion battery or other battery packages, a protection circuit module is installed which includes a protection circuit for preventing the battery from being degraded by overheat caused by overcurrent due to electrical short circuit, erroneous charging (with a large voltage or a reverse voltage), and others.

For example, Japanese Laid Open Patent Application No. 2001-61232 (below, referred to as “reference 1”) discloses a protection circuit in which current control transistors that are MOS transistors are connected in series between a secondary battery and external connection terminals with a charger or a load connected thereto. When abnormal charging occurs a current control transistor for controlling the charging process is turned off to stop the charging, and when abnormal discharging occurs, a current control transistor for controlling the discharging process is turned off to stop the discharging.

FIG. 11 is a circuit diagram illustrating an example of a protection circuit of a secondary battery in the related art.

As shown in FIG. 11, a secondary battery 48 is connected between external terminals 44a, 44b on the battery side, an external device 50 is connected between external terminals 46a, 46b on the load side, the battery side external terminal 44a and the load side external terminal 46a are connected through a charging-discharging circuit 52a on the positive side, and the battery side external terminal 44b and the load side external terminal 46b are connected through a charging-discharging circuit 52b on the negative side. A current control transistor 54 and a current control transistor 56 are connected in series to the charging-discharging circuit 52b. The current control transistor 54 and the current control transistor 56 are field effect transistors.

A protection IC (integrated circuit) chip 58 is connected between the charging-discharging circuit 52a and the charging-discharging circuit 52b, a power voltage terminal 58a of the protection IC chip 58 is connected to the charging-discharging circuit 52a through a resistor 60, and a ground terminal 58b is connected to the charging-discharging circuit 52b between the battery side external terminal 44b and the current control transistor 54, a charger negative voltage input terminal 58c is connected to the charging-discharging circuit 52b between the battery side external terminal 46b and the current control transistor 56 through a resistor 62. A condenser 64 is connected between the power voltage terminal 58a and the ground terminal 58b. An over-discharging detection output terminal 58d is connected to the gate of the current control transistor 54, and an over-discharging detection output terminal 58e is connected to the gate of the current control transistor 56. A PTC element 66 is connected to the battery side external terminal 44b and the secondary battery 48.

In a protection circuit module of the related art having the above protection circuit, packaged modules are used for the current control transistor 54, the current control transistor 56, and the protection IC chip 58, which are semiconductor parts, and these packaged modules are mounted on a circuit board.

However, since the packaged modules are connected to semiconductor chips and lead lines by bonding wire, the cost of the packaged modules is high. In addition, in the current control transistors 54, 56, since the semiconductor chips are electrically connected to the circuit board through lead lines by bonding wire, it is difficult to reduce the resistance in an ON state.

There is a well known COB (Chip On Board) technique in this technical field, in which bare chips are mounted on the circuit board, and chip electrodes are electrically connected to the circuit board through the bonding wires. For example, Japanese Laid Open Patent Application No. 2002-141506 (below, referred to as “reference 2”) and Japanese Laid Open Patent Application No. 2002-314029 (below, referred to as “reference 3”) disclose this technique. Specifically, reference can be made to pages 2, 4 and FIG. 2 and FIG. 3 in reference 2, and to pages 2, 3 and FIG. 14 and FIG. 15 in reference 3.

However, since expensive metal materials are used for the bonding wires, it is difficult to reduce the cost. In addition, in the current control transistors, since the semiconductor chips are electrically connected to the circuit board through the bonding wire, it is difficult to reduce the resistance in an ON state.

There is a well known Flip Chip Mounting technique in this technical field, in which a bare chip having plural external connection terminals arranged in a plane is mounted on the circuit board to face downward. For example, Japanese Laid Open Patent Application No. 10-112481 (below, referred to as “reference 4”) discloses this technique.

Further, a protection circuit module can be obtained by mounting the current control transistors and the protection IC chip, which are semiconductor parts, on the circuit board in a face-down manner. For example, Japanese Laid Open Patent Application No. 2000-307052 (below, referred to as “reference 5”) discloses this technique.

By mounting the semiconductor parts on the circuit board in the face-down manner, the cost can be reduced compared to the wire bonding technique, and the area for mounting the semiconductor parts can be reduced. Further, it is possible to reduce the ON-state resistance of the field effect transistors.

When sealing semiconductor parts mounted in the face-down manner with a sealing resin covering the semiconductor parts, for example, as described in reference 2, with an under-fill resin applied below the semiconductor parts, it is possible to prevent variation of performance of the semiconductor parts, and prevent generation of voids caused by air in the space below the semiconductor parts.

As described in references 3 and 5, in a device with mounted electronic parts, which includes both semiconductor parts mounted on the circuit board in the face-down manner and other electronic parts, when applying a sealing resin in the mounting area of the semiconductor parts and the mounting area of the electronic parts, in the mounting area of the semiconductor parts, below which the under-fill resin is applied, the under-fill resin projects out of the semiconductor parts and is taper-shaped. Because of the taper-shaped under-fill resin, it is possible to prevent air bubbles from entering into the sealing resin near the semiconductor parts.

However, in the mounting area of the electronic parts other than the semiconductor parts, small air bubbles may enter into the sealing resin near the electronic parts. The small air bubbles in the sealing resin near the electronic parts grow especially when being heated, and this influences the outer appearance of the device; additionally, voids may be formed due to the air bubbles, and this may degrade reliability of the device with mounted electronic parts.

### DISCLOSURE OF THE INVENTION

The present invention may solve one or more of the problems of the related art.

A preferred embodiment of the present invention may provide a method of fabricating a device including plural electronic parts mounted on a circuit board with mounting areas for mounting the electronic parts covered by a sealing resin, and able to prevent small air bubbles from entering into the sealing resin near the electronic parts.

Other preferred embodiments of the present invention may provide a device having plural electronic parts mounted on the circuit board, a protection circuit module of a secondary battery, and a battery package using the protection circuit module.

According to a first aspect of the present invention, there is provided a method of fabricating a device including plural electronic parts mounted on a circuit board with mounting areas for mounting the electronic parts covered by a sealing resin, said method comprising the steps of, before applying the sealing resin:

applying an under-fill resin near two or more electronic parts with plural nozzles at the same time; and

hardening the under-fill resin to form a taper-shaped structure around the two or more of the electronic parts.

Here, the “under-fill resin” means a liquid resin with an insulating material as a main ingredient.

According to the present invention, the under-fill resin near the electronic parts fills the space between the electronic parts and the circuit board, and when the under-fill resin is hardened, the under-fill resin projects out of the electronic parts and forms a taper-shaped structure.

In the present invention, the areas where the under-fill resin is applied are not limited to the space between the electronic parts and the circuit board, nor to the areas near the electronic parts. The under-fill resin can be applied on the upper surface of the electronic parts so that the under-fill resin covers the electronic parts and forms a taper-shaped structure on the side surface of the electronic parts.

In addition, among the plural nozzles, some or all of the nozzles may be used to apply the under-fill resin on the areas between the electronic parts, and one of the nozzles may be used to apply the under-fill resin on the electronic parts.

Preferably, the nozzles may be connected to the same under-fill resin supplier.

Preferably, the nozzles may have two or more different diameters.

Preferably, each of the nozzles may have a taper-shaped front end with a thin end portion.

Preferably, each of the electronic parts covered by the sealing resin may be enclosed by one taper-shaped structure. However, the present invention is not limited to this; for example, there may be some electronic parts around which the taper-shaped structure is not provided.

According to a second aspect of the present invention, there is provided a device, comprising:

a circuit board;

plural electronic parts mounted on the circuit board, the mounting areas for mounting the electronic parts being covered by a sealing resin; and

under-fill resin taper-shaped structures around each of the electronic parts.

According to a third aspect of the present invention, there is provided a secondary battery protection circuit module, comprising:

a circuit board;

plural electronic parts mounted on the circuit board, the mounting areas for mounting the electronic parts being covered by a sealing resin;

under-fill resin taper-shaped structures around each of the electronic parts;

one or more electronic part mounting areas on one surface of the circuit board;

one or more semiconductor part mounting areas on the one surface of the circuit board for mounting one or more semiconductor parts, the semiconductor part being an electronic part having plural external connection terminals arranged in the same plane;

plural battery side external terminals on the one surface of the circuit board; and

plural load side external terminals on another surface of the circuit board,

wherein

the semiconductor part is a bare chip and is mounted on the one surface of the circuit board in a face-down manner.

According to a fourth aspect of the present invention, there is provided a battery package, comprising:

a secondary battery protection circuit module;

a secondary battery;

a connection member that electrically connects the secondary battery protection circuit module and the secondary battery; and

a housing that accommodates the secondary battery and the connection member,

wherein

the secondary battery protection circuit module includes:

a circuit board;

plural electronic parts mounted on the circuit board, the mounting areas for mounting the electronic parts being covered by a sealing resin;

under-fill resin taper-shaped structures around each of the electronic parts;

one or more electronic part mounting areas on one surface of the circuit board;

one or more semiconductor part mounting areas on the one surface of the circuit board for mounting one or more semiconductor parts, the semiconductor part being an electronic part having plural external connection terminals arranged in the same plane;

plural battery side external terminals on the one surface of the circuit board; and

plural load side external terminals on another surface of the circuit board,

wherein

the semiconductor part is a bare chip and is mounted on the one surface of the circuit board in a face-down manner.

According to an embodiment of the present invention, because before applying the sealing resin, the under-fill resin is applied near the electronic parts with plural nozzles at the same time, and the under-fill resin is hardened to form a taper-shaped structure around plural electronic parts, due to the presence of the taper-shaped structure, it is possible to prevent air bubbles from entering into the sealing resin near the electronic parts when forming the sealing resin, prevent the outer appearance of the device from being influenced, and prevent degradation of reliability of the device caused by growth of the air bubbles and generation of voids when being heated.

In addition, because the under-fill resin is applied near the electronic parts with plural nozzles at the same time, the time used for applying the under-fill resin is shortened compared to the case in which the under-fill resin is applied near the electronic parts sequentially.

In addition, because the nozzles may be connected to the same under-fill resin supplier, it is possible to apply the under-fill resin at plural positions at the same time with one driving system, which is used to eject the under-fill resin. Thus, it is possible to reduce the fabrication cost compared to using plural driving systems.

In addition, since the nozzles may have two or more different diameters, it is possible to change the amount of the under-fill resin to be applied according to the areas in which the under-fill resin is to be applied; thus, it is possible to appropriately adjust the amount of the under-fill resin according to sizes of the electronic parts, or the number of the electronic parts in one area where the under-fill resin is to be applied.

In addition, because each of the nozzles may have a taper-shaped front end with a thin end portion, for example, even when contaminants adhere to the front end of the nozzle, it is possible to reduce deviation of resin application positions caused by attachment to the front end of the nozzle, and this improves precision of applying the under-fill resin.

In addition, since each of the electronic parts covered by the sealing resin may be enclosed by one taper-shaped structure, it is possible to prevent air bubbles from entering into the sealing resin near the electronic parts mounted in the area covered by the sealing resin.

According to the device of an embodiment of the present invention, which has plural electronic parts mounted on a circuit board, because the device includes taper-shaped structures around each of the electronic parts, it is possible to prevent air bubbles from entering into the sealing resin near the electronic parts, and prevent degradation of reliability of the device caused by growth of the air bubbles and generation of voids when being heated.

According to the secondary battery protection circuit module of an embodiment of the present invention, since taper-shaped structures are formed around plural electronic parts and plural semiconductor parts, it is possible to prevent air bubbles from entering into the sealing resin near the electronic parts, prevent influence on the outer appearance of the device, and prevent degradation of reliability of the device caused by growth of the air bubbles and generation of voids when being heated.

In addition, in the circuit board, since plural battery side external terminals are arranged on one surface of the circuit board, and plural load side external terminals are arranged on the other surface of the circuit board, the area of the circuit board can be reduced compared to the case in which the battery side external terminals and the load side external terminals are arranged on the same side of the circuit board, so that it is possible to reduce the size of the secondary battery protection circuit module.

Further, since the semiconductor part is mounted on the circuit board in a face-down manner, it is possible to reduce the fabrication cost compared to using the wire bonding technique, and it is possible to reduce the mounting area of the semiconductor part. That is, with the secondary battery protection circuit module of the present invention, it is possible to reduce the size of the protection circuit module and reduce the fabrication cost.

According to the battery package of the present invention, since the battery package includes the above secondary battery protection circuit module, a secondary battery, a connection member that electrically connects the secondary battery protection circuit module and the secondary battery, and a housing that accommodates the secondary battery and the connection member, it is possible to further improve reliability, and it is possible to reduce the size and the fabrication cost of the battery package of the present invention.

These and other objects, features, and advantages of the present invention will become more apparent from the following detailed description of preferred embodiments given with reference to the accompanying drawings.

### BRIEF DESCRIPTION OF THE DRAWINGS

FIG. 1A through FIG. 1C are views of a protection circuit module according to an embodiment of the present invention, where FIG. 1A is a schematic perspective view of the front side of the protection circuit module, FIG. 1B is a schematic perspective view of the back side of the protection circuit module, and FIG. 1C is a cross-sectional view of the protection circuit module taken along the AA line in FIG. 1A;

FIG. 2A is an enlarged cross-sectional view of a mounting area portion of a protection IC chip in the protection circuit module in FIG. 1A through FIG. 1C;

FIG. 2B is an enlarged cross-sectional view of a mounting area portion of a field effect transistor chip in the protection circuit module in FIG. 1A through FIG. 1C;

FIG. 2C is an enlarged cross-sectional view of a mounting area portion of an electronic part in the protection circuit module in FIG. 1A through FIG. 1C;

FIG. 3A and FIG. 3B are plan views illustrating the protection circuit module of the present embodiment connected with a connection member for electrically connecting the secondary battery protection circuit module and the secondary battery, where FIG. 3A is a plan view of the front surface of the protection circuit module and the connection member, and FIG. 3B is a plan view of the back surface of the protection circuit module and the connection member;

FIG. 4 is a partial cross-sectional view illustrating an example of a battery package according to the present embodiment;

FIG. 5A through FIG. 5D are plan views schematically illustrating a collective circuit board for explaining a method of fabricating the circuit board 2 of the present embodiment;

FIG. 6A through FIG. 6F are cross-sectional views of portions of the collective circuit board for explaining the method of fabricating the circuit board 2 of the present embodiment;

FIG. 7A through FIG. 7C are cross-sectional views illustrating portions of the circuit board 2 with plural electronic parts mounted for explaining the method of fabricating the circuit board 2 of the present embodiment;

FIG. 8 is a schematic plan view of a mechanism used in the step in FIG. 7C for applying the under-fill resin;

FIG. 9A through FIG. 9D are schematic views for illustrating operation of the nozzle 33a of the present invention in comparison with a nozzle 33e in the related art;

FIG. 10A is a perspective view of a taper-shaped insulating resin structure near an electronic part 15;

FIG. 10B is a cross-sectional view of the electronic part 15 taken along an XX line in FIG. 10A; and

FIG. 11 is a circuit diagram illustrating an example of a protection circuit of a secondary battery in the related art.

### BEST MODE FOR CARRYING OUT THE INVENTION

Below, preferred embodiments of the present invention are explained with reference to the accompanying drawings.

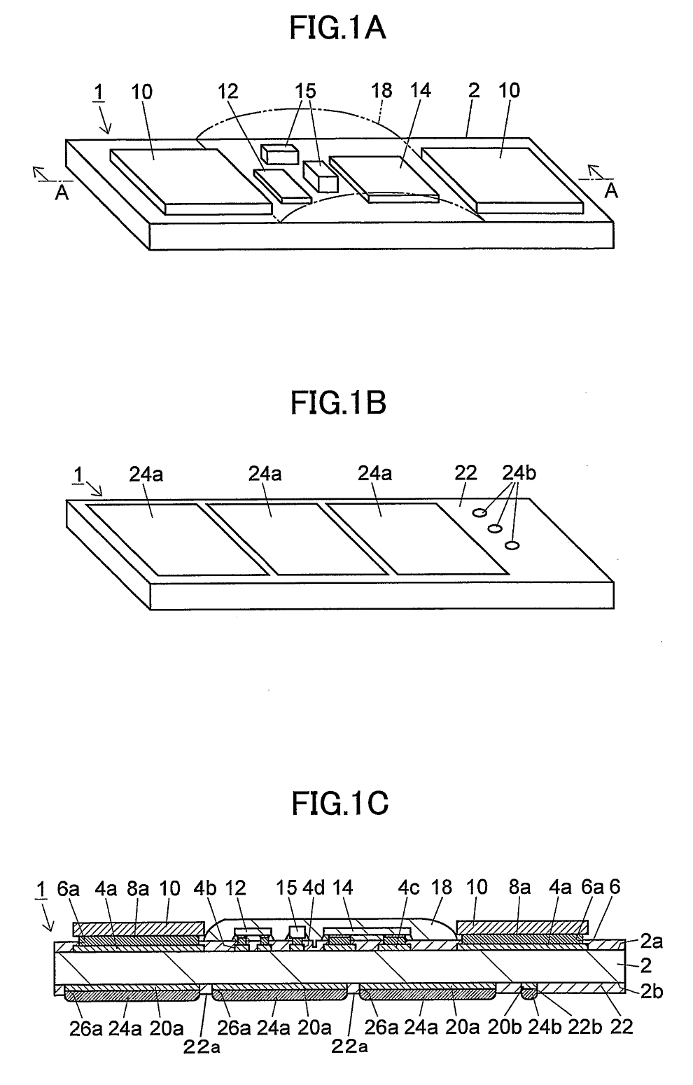

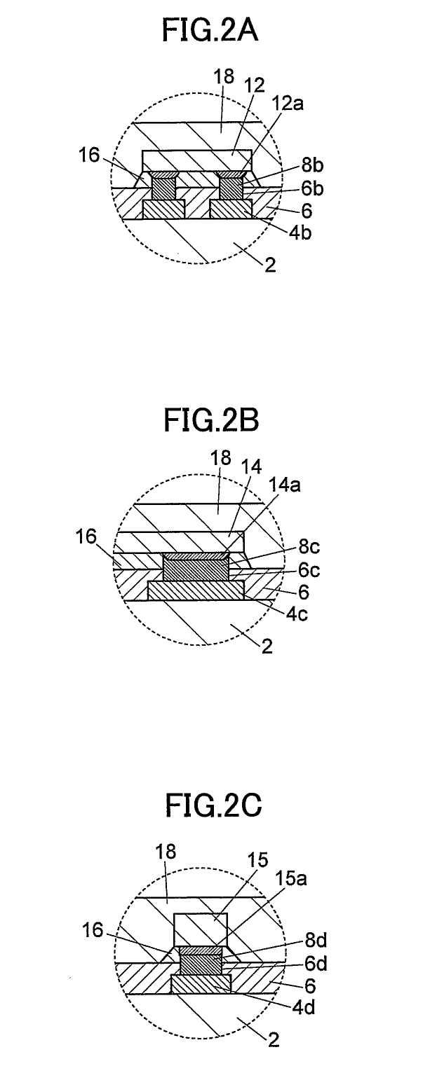

Below, a protection circuit module according to an embodiment of the present invention is described with respect to FIG. 1A through FIG. 1C and FIG. 2A through FIG. 2C.

FIG. 1A through FIG. 1C are views of a protection circuit module according to an embodiment of the present invention, where FIG. 1A is a schematic perspective view of the front side of the protection circuit module, FIG. 1B is a schematic perspective view of the back side of the protection circuit module, FIG. 1C is a cross-sectional view of the protection circuit module taken along the AA line in FIG. 1A.

As shown in FIG. 1C, the protection circuit module 1 includes a circuit board 2, and on one surface 2a of the circuit board 2, there are formed two battery side external terminals 4a, plural electrodes 4b for use of the protection IC chip, plural electrodes 4c for use of the field effect transistor chip, plural electrodes 4d for use of electronic parts, and circuit patterns (not illustrated).

For example, the battery side external terminals 4a, the protection IC chip electrodes 4b, the field effect transistor chip electrodes 4c, the electronic part electrodes 4d, and the circuit pattern are made of copper; the protection IC chip electrodes 4b, the field effect transistor chip electrodes 4c, and the electronic part electrodes 4d are arranged between the two battery side external terminals 4a.

On the surface 2a of the circuit board 2, an insulating material layer 6 is formed, and on the insulating material layer 6, there are formed openings 6a corresponding to the battery side external terminals 4a, openings 6b (see FIG. 2A) corresponding to the protection IC chip electrodes 4b, openings 6c (see FIG. 2B) corresponding to the field effect transistor chip electrodes 4c, and openings 6d (see FIG. 2C) corresponding to the electronic part electrodes 4d.

A metal plate 10, such as a nickel plate, is disposed on the battery side external terminals 4a with solder 8a in the openings 6a in between.

In the area where the protection IC chip electrodes 4b are formed, a bare protection IC chip (a semiconductor part) 12 is mounted in a face-down manner. Specifically, external connection terminals 12a are arranged on a surface of the protection IC chip 12; the external connection terminals 12a are connected with the protection IC chip electrodes 4b through solder 8b in the openings 6b, and thereby, the protection IC chip 12 is mounted on the circuit board 2.

In the area where the field effect transistor chip electrodes 4c are formed, a bare field effect transistor chip (a semiconductor part) 14 is mounted in a face-down manner. Specifically, external connection terminals 14a are arranged on a surface of the field effect transistor chip 14; the external connection terminals 14a are connected with the field effect transistor chip electrodes 4c through solder 8c in the openings 6c, and thereby, the field effect transistor chip 14 is mounted on the circuit board 2. For example, the field effect transistor chip 14 includes two serially connected field effect transistors.

In the area where the electronic part electrodes 4d are formed, an electronic part 15 is mounted. For example, the electronic part 15 may be a thermistor element (such as a PTC element), a resistor, or a condenser.

Electrodes 15a of the electronic part 15 are connected with the electronic part electrodes 4d through solder 8d in the openings 6d, and thereby, the electronic part 15 is mounted on the circuit board 2.

For example, the external connection terminals 12a of the protection IC chip 12 and the external connection terminals 14a of the field effect transistor chip 14 may be fabricated by electroless plating.

FIG. 2A is an enlarged cross-sectional view of a mounting area portion of a protection IC chip in the protection circuit module in FIG. 1A through FIG. 1C.

FIG. 2B is an enlarged cross-sectional view of a mounting area portion of a field effect transistor chip in the protection circuit module in FIG. 1A through FIG. 1C.

FIG. 2C is an enlarged cross-sectional view of a mounting area portion of an electronic part in the protection circuit module in FIG. 1A through FIG. 1C.

As shown in FIG. 2A through FIG. 2C, an under-fill resin (taper-shaped structure) 16, which is formed from a resin material, is supplied in the space between the protection IC chip 12 and the insulating material layer 6, and in the space between the field effect transistor chip 14 and the insulating material layer 6. The under-fill resin 16 may be an epoxy-based resin, or a silicon-based resin. In addition, the under-fill resin 16 may include silica particles, or may be free of silica particles.

Fillet-shaped structures (taper-shaped structures), which are formed by the under-fill resin 16, are formed between the electronic part 15 and the insulating material layer 6, and in the area around the electronic parts 15 including the area near the solder 8d, which is used for mounting the electronic parts 15.

A sealing resin 18 is disposed on portions of the insulating material layer 6 between two metal plates 10, including the mounting area of the protection IC chip 12, the mounting area of the field effect transistor chip 14, and the mounting area of the electronic parts 15. The sealing resin 18 covers and protects the protection IC chip 12, the field effect transistor chip 14, and the electronic parts 15.

On the back surface of the circuit board 2, which is opposite to the surface 2a, for example, there are formed three load side external terminals 20a, and plural test terminals 20b. For example, the load side external terminals 20a and the test terminals 20b are made of copper.

On the back surface 2b of the circuit board 2, an insulating material layer 22 is formed, and in the insulating material layer 22, there are formed openings 22a corresponding to the load side external terminals 20a, and openings 22b corresponding to the test terminals 20b.

A gold plating layer 24a is formed on the surface of the load side external terminals 20a, and a gold plating layer 24b is formed on the surface of the test terminals 20b.

In the present embodiment, since the battery side external terminals 4a are arranged on the surface 2a of the circuit board 2, and the load side external terminals 20a are arranged on the back surface 2b of the circuit board 2, the area of the circuit board 2 can be reduced compared to the case in which the battery side external terminals 4a and the load side external terminals 20a are arranged on the same side of the circuit board 2, and this reduces the size of the protection circuit module 1.

Since the protection IC chip 12 and the field effect transistor chip 14 are mounted on the surface 2a of the circuit board 2 in a face-down manner, it is possible to reduce the fabrication cost compared to using the wire bonding technique, and it is possible to reduce the mounting areas of the protection IC chip 12 and the field effect transistor chip 14.

Since the field effect transistor chip 14 is mounted on the surface 2a of the circuit board 2 in a face-down manner, it is possible to reduce the ON state resistance of the field effect transistor chip 14.

Since the protection IC chip 12, the field effect transistor chip 14, and the electronic parts 15 are covered by the sealing resin 18, the sealing resin 18 can protect the protection IC chip 12, the field effect transistor chip 14, and the electronic parts 15.

The insulating material layer 6 is formed on the surface 2a of the circuit board 2, which includes the openings 6a, 6b, and 6c corresponding to the battery side external terminals 4a, the protection IC chip electrodes 4b, and the field effect transistor chip electrodes 4c. The protection IC chip 12 and the field effect transistor chip 14 are mounted on the circuit board 2 through solder 8b, 8c in the openings 6b, and 6c. Therefore, the insulating material layer 6 exists between the external connection terminals 12a of adjacent protection IC chips 12, and between the external connection terminals 14a of the field effect transistor chip 14; this prevents an electrical short circuit between adjacent external connection terminals 12a, and adjacent external connection terminals 14a.

Since the gold plating layer 24a is formed on the surface of the load side external terminals 20a, it is possible to obtain stable electrical connection between the load side external terminals 20a and load terminals, for example, load terminals of a portable device or a charger. Further, since the gold plating layer 24b is formed on the surface of the test terminals 20b, it is possible to obtain stable electrical connection during a test.

Since fillet-shaped structures, which are formed by the under-fill resin 16, are arranged between the electronic part 15 and the insulating material layer 6 and in the area near the solder 8d, which is used for mounting the electronic parts 15, it is possible to prevent air bubbles from entering into the sealing resin 18 near the electronic parts 15, prevent the outer appearance of the device from being influenced, and prevent degradation of reliability of the device caused by growth of the air bubbles and generation of voids when being heated.

In the above, it is described that the semiconductor parts include one protection IC chip 12 and one field effect transistor chip 14, but the protection circuit module of the present embodiment is not limited to this example. For example, the semiconductor parts may include one protection IC chip 12 and two field effect transistor chips 14, or any other types or numbers of semiconductor parts. Further, the electronic parts 15 may also include any types or numbers of electronic parts.

In addition, in the above, it is described that there are three load side external terminals 20a, but the protection circuit module of the present embodiment is not limited to this example. For example, there may be two or four or more load side external terminals 20a.

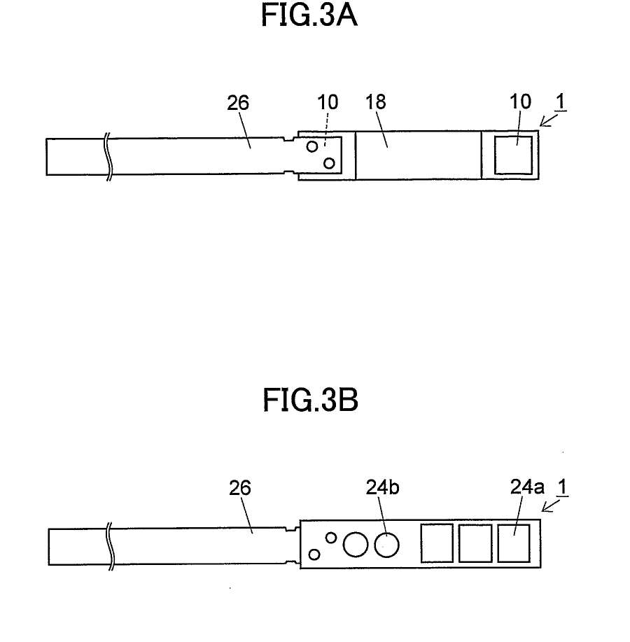

FIG. 3A and FIG. 3B are plan views illustrating the protection circuit module of the present embodiment connected with a connection member for electrically connecting the secondary battery protection circuit module and the secondary battery, where FIG. 3A is a plan view of the front surface of the protection circuit module and the connection member, and FIG. 3B is a plan view of the back surface of the protection circuit module and the connection member.

Here, the same reference numbers are assigned to the same elements as those shown in FIG. 1A through FIG. 1C, and overlapping descriptions are omitted.

A nickel strip member 26 serving as the connection member is electrically connected, by spot welding, to one of the two metal plates 10, which are connected to the front surface of the protection circuit module 1, to electrically connect the secondary battery protection circuit module and the secondary battery.

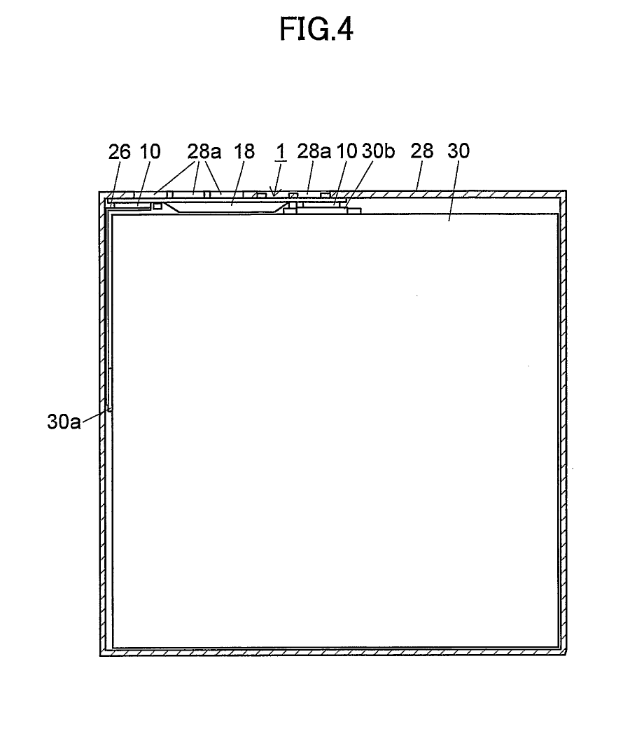

FIG. 4 is a partial cross-sectional view illustrating an example of a battery package according to the present embodiment.

As shown in FIG. 4, in a housing 28, which is made from an insulating material, there are arranged the protection circuit module 1, the secondary battery 30, and the connection member 26. The outside surface of the protection circuit module 1 corresponds to the back surface of the circuit board 2, on which the gold plating layers 24a, 24b are formed on the surfaces of the load side external terminals 20a and on the surface of the test terminal 20b. The inner surface of the protection circuit module 1 corresponds to the front surface of the circuit board 2, on which the metal plates 10 and the sealing resin 18 are disposed. Openings 28a are formed on the housing 28 corresponding to the gold plating layers 24a, 24b on the load side external terminals 20a and the test terminal 20b.

A nickel strip member 26, which is welded to one of the two metal plates 10 of the protection circuit module 1, is connected to an electrode 30a of the secondary battery 30. The other metal plate 10, to which the nickel strip member 26 is not connected, is connected to an electrode 30b of the secondary battery 30.

Due to the protection circuit module 1, which has a small size and low cost, it is possible to reduce the size and cost of the battery package.

In FIG. 4, it is shown that one metal plate 10 is directly connected to the electrode 30b of the secondary battery 30, but the present invention is not limited to this example. Both of the two metal plates 10 may be connected to the electrodes 30a, 30b of the secondary battery 30 through a nickel wire.

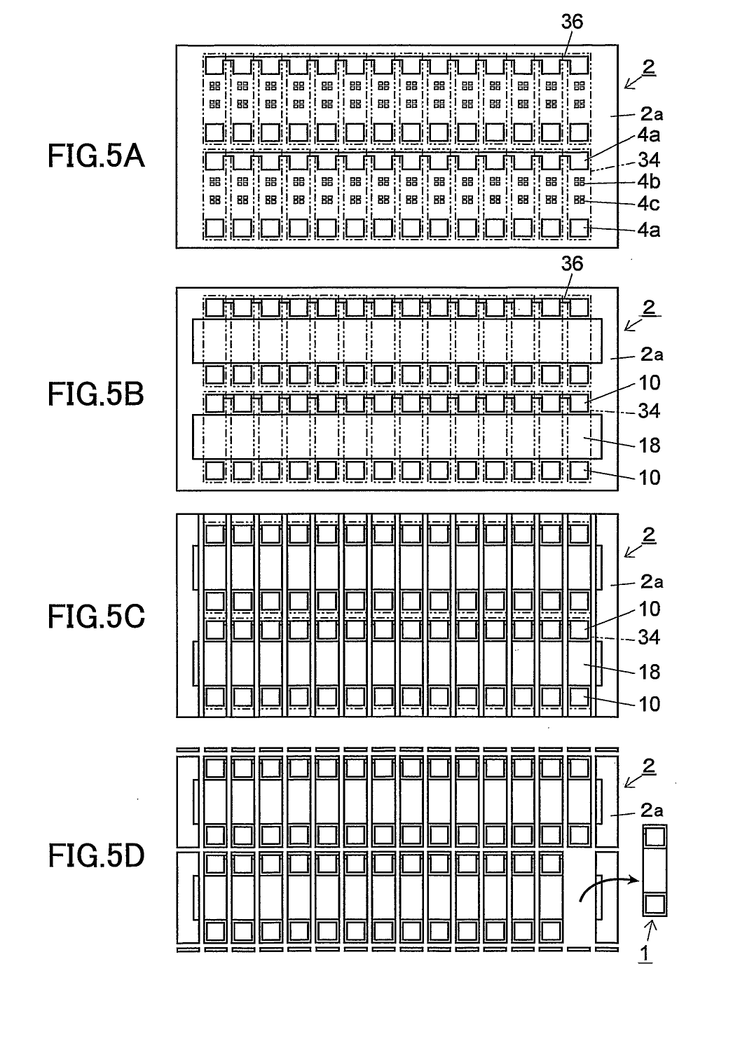

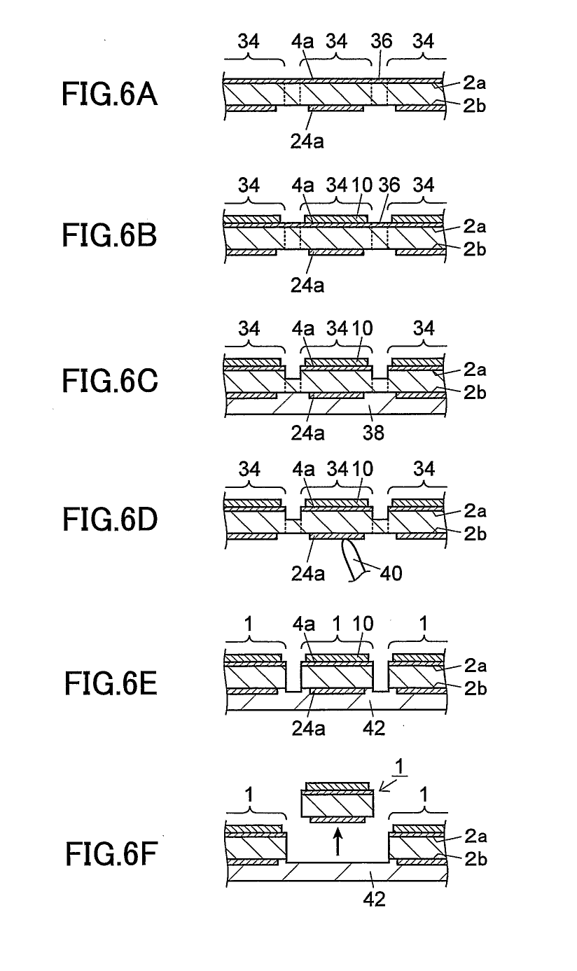

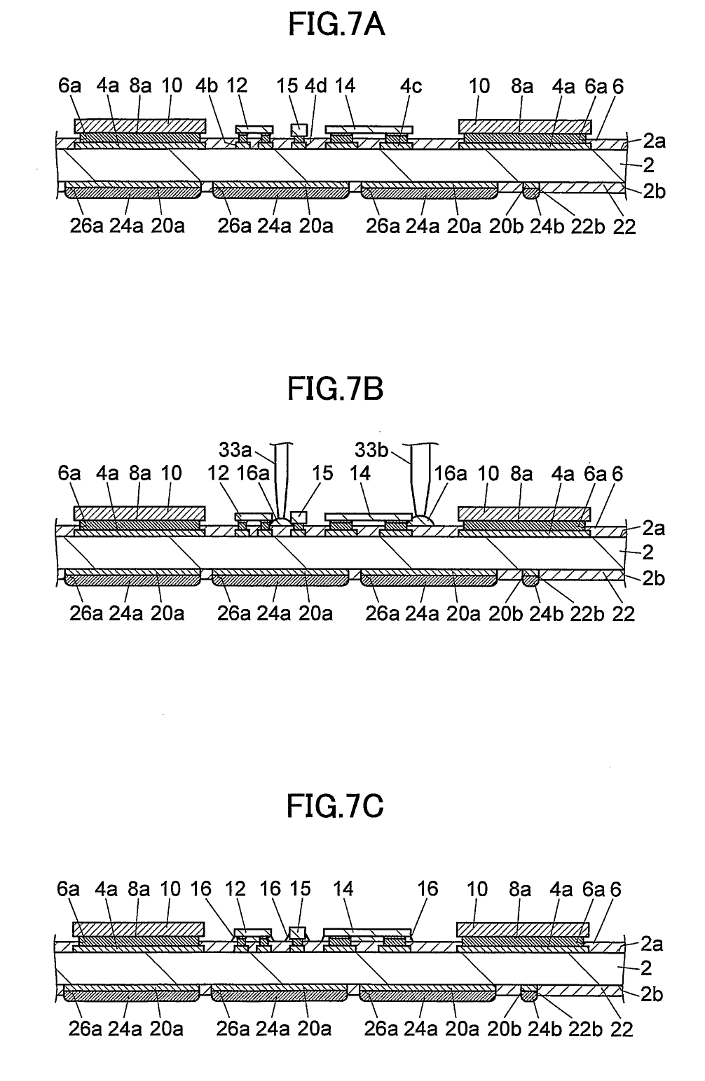

Below, a method of fabricating the circuit board of the present embodiment is described with reference to FIG. 5A through FIG. 5C, FIG. 6A through FIG. 6D, and FIG. 7A through FIG. 7F.

In the following, the same reference numbers are assigned to the same or the corresponding elements as those described in FIG. 1A through FIG. 1C.

FIG. 5A through FIG. 5D are plan views schematically illustrating a circuit board (here, referred to as a “collective circuit board”), for explaining a method of fabricating the circuit board 2 of the present embodiment.

FIG. 6A through FIG. 6F are cross-sectional views of portions of the collective circuit board.

As shown in FIG. 5A, for example, a collective circuit board 2 is prepared, which includes plural rectangular circuit board regions 34 (indicated with double dot—dashed lines). In FIG. 5A, there are two rows and fourteen columns of the circuit board regions 34 arranged in a matrix manner. In each of the circuit board regions 34, on one surface 2a of the collective circuit board 2, there are formed two battery side external terminals 4a, plural protection IC chip electrodes 4b, plural field effect transistor chip electrodes 4c, plural electronic part electrodes 4d (see FIG. 7A), and circuit patterns (not shown).

In FIG. 5A, on the surface 2a of the collective circuit board 2, there are formed plating wires 36 between every two adjacent battery side external terminals 4a in the width direction of the battery side external terminals 4a. Although not illustrated, the plating wires 36 are connected to a plating electrode arranged at one end of the collective circuit board 2.

As shown in FIG. 6A, in each of the circuit board regions 34, on the back surface 2b of the collective circuit board 2, there are a gold plating layer 24a formed on the surface of the load side external terminals (not illustrated), and a gold plating layer (not illustrated) formed on the surface of the test terminal (not illustrated).

The metal material (not illustrated), such as the load side external terminals or the test terminal, which is formed on the back surface 2b of the collective circuit board 2 and underlie the gold plating layer 24a, is not shorted between every two adjacent circuit board regions 34. The metal material formed on the back surface 2b of the collective circuit board 2 is electrically connected to the plating wires 36 via through-holes (not illustrated) formed in the collective circuit board 2.

The gold plating layer 24a is formed during a plating process when a voltage is applied, via the plating wire, on the metal material formed on the back surface 2b of the collective circuit board 2.

FIG. 7A through FIG. 7C are cross-sectional views illustrating portions of the circuit board 2 with plural electronic parts mounted for explaining the method of fabricating the circuit board 2 of the present embodiment.

As shown in FIG. 7A (also refer to FIG. 1A through FIG. 1C), the metal plates 10, the protection IC chip 12, the field effect transistor chip 14, and the electronic parts 15 are mounted on the battery side external terminals 4a, the protection IC chip electrodes 4b, the field effect transistor chip electrodes 4c, and the electronic part electrodes 4d, respectively, with the solder 8a.

Next, as shown in FIG. 7B, near the mounting areas of the protection IC chip 12, the field effect transistor chip 14, and the electronic parts 15, for example, two nozzles 33a and 33b are used to apply the under-fill resin 16a at two positions of each chip region 2 at the same time. Specifically, for the field effect transistor chip 14, which has a relatively large planar area, and requires a relatively large amount of the under-fill resin 16a, the nozzle 33b having a relatively large diameter is used to apply the under-fill resin 16a; for the protection IC chip 12 and the electronic parts 15, which have a relatively small planar area, and require a relatively small amount of the under-fill resin 16a, the nozzle 33a having a relatively small diameter is used to apply the under-fill resin 16a.

In the area between the protection IC chip 12 and the electronic parts 15, the nozzle 33a is used to apply the under-fill resin 16a to cover the protection IC chip 12 and the electronic parts 15.

The under-fill resin 16a applied near the mounting areas of the protection IC chip 12, the field effect transistor chip 14, and the electronic parts 15 spreads to the space below and the space surrounding the protection IC chip 12, the field effect transistor chip 14, and the electronic parts 15.

Next, as shown in FIG. 7C, the under-fill resin 16a is hardened to form taper-shaped under-fill resin structures 16 below and surrounding the protection IC chip 12, the field effect transistor chip 14, and the electronic parts 15.

Next, as shown in FIG. 5B, the sealing resin 18 is applied and hardened subsequently along the width direction of the circuit board regions 34 to cover the protection IC chip 12, the field effect transistor chip 14, and the electronic parts 15. In this step, since taper-shaped under-fill resin structures 16 are formed below and surrounding the protection IC chip 12, the field effect transistor chip 14, and the electronic parts 15, it is possible to prevent small air bubbles from entering into the sealing resin 18.

Next, as shown in FIG. 6C (also refer to FIG. 5C), a dicing tape 38 is stuck on the back surface 2b of the collective circuit board 2. By employing a dicing technique, cutting grooves are formed, from the side of the surface 2a of the collective circuit board 2, in the portions of the circuit board 2 between two adjacent circuit board regions 34 along the width direction of the circuit board regions 34 so that the plating wires 36 are cut. Due to this, the circuit board regions 34 are electrically isolated from each other. Here, the portions of the circuit board 2, in which the cutting grooves are formed, are covered by the insulating material layer 6. When the insulating material layer 6 is a resist, the interval between two adjacent circuit board regions 34 is determined while considering the following factors, such as the width of cutting grooves, the structure of the resist, layer configuration (for example, in a two-layer resist structure, the upper resist is made to recede from the lower resist), and cohesive force, so that the resist is not removed or damaged.

Next, as shown in FIG. 6D, after the dicing tape 38 is removed, a test terminal 40 is put in electrical contact with the gold plating layer 24 of the circuit board regions 34 to test the performance of the collective circuit board 2. Based on the test results, good products and defective products are identified and marks of lot numbers are made.

Next, as shown in FIG. 6E, a dicing tape 42 is stuck on the back surface 2b of the collective circuit board 2. By employing the dicing technique, from the side of the surface 2a of the collective circuit board 2, the circuit board 2 is cut at positions between two adjacent circuit board regions 34 to cut out the protection circuit module 1.

Next, as shown in FIG. 6F (also refer to FIG. 5D), the dicing tape 42 is stretched at its corners to facilitate removal of the protection circuit module 1. Further, ultra-violet rays are irradiated onto the dicing tape 42 to weaken the adhesive force of the dicing tape 42. Then, a rod-like jig (not illustrated) is used to push up one protection circuit module 1, and the protection circuit module 1 is taken out by vacuum suction using a pick-up jig. Next, inspection is performed to detect defects in the appearance.

In the collective circuit board of a protection circuit module in the related art, on the back surface 2b of the collective circuit board 2, the metal material parts underlying the gold plating layer are connected with each other via plating wires between two adjacent circuit board regions 34, so the test is performed after cutting out the protection circuit module. In addition, even when it is desired to cut the plating wires from the side of the back surface 2b of the collective circuit board 2, since semiconductor parts are mounted on the front surface 2a of the collective circuit board 2, a dicing tape cannot be stuck thereon.

In contrast, according to the fabrication method of the present invention, since the plating wires are not formed on the back surface 2b of the collective circuit board 2, after cutting the plating wires on the front surface 2a of the collective circuit board 2, the test can be performed before cutting out the protection circuit module.

Then, by using a tester to test plural circuit board regions of a collective circuit board at the same time, it is easy to perform the electrical test of the protection circuit modules compared to testing individual protection circuit module one by one, and it is possible to reduce the time and cost for the test, which reduces the fabrication cost of the protection circuit module.

In the above, it is described that the collective circuit board 2 has a two-circuit-layer structure, that is, the front surface 2a and the back surface 2b, but the present embodiment is not limited to this. For example, the collective circuit board 2 may have a three-circuit-layer structure, in which plating wires may be formed on the first layer or the second layer from the front surface side (that is, the side on which the semiconductor parts are to be mounted). Alternatively, the collective circuit board 2 may have a four-circuit-layer structure, in which plating wires may be formed on the first layer, the second layer, or the third layer from the front surface side, or the combination of them. That is, as long as the plating wires are not disposed on the back surface 2b, after cutting the plating wires on the front surface of the collective circuit board, the test can be performed before cutting out the protection circuit module.

In the above, it is described that the cutting grooves are formed along the longitudinal direction of the circuit board regions 34, but the present embodiment is not limited to this. The cutting grooves for cutting the plating wires may be formed in any direction. Further, the cutting grooves may be formed in two directions intersecting each other.

In the above embodiments, the under-fill resin 16 filling in the space below the semiconductor parts 14 mounted in a face-down manner is formed near other electronic parts 15, such as thermistor elements (such as PTC elements), resistors, or condensers to form a taper-shaped structure surrounding the other electronic parts 15. The structure, in which an insulating resin such as the under-fill resin is disposed around the electronic parts other than the semiconductor parts, is applicable to a device with electronic parts mounted other than a protection circuit module of a secondary battery, and, for example, there is no limitation to the arrangement of the electrodes and terminals.

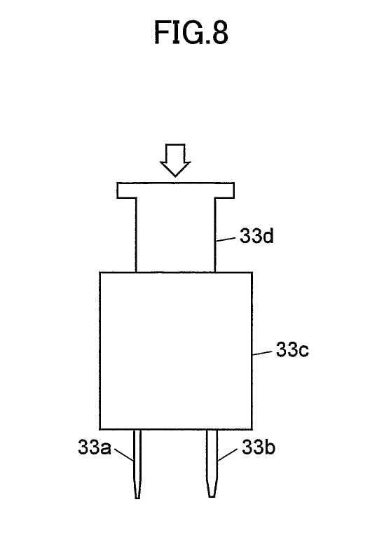

FIG. 8 is a schematic plan view of a mechanism used in the step in FIG. 7C for applying the under-fill resin.

As shown in FIG. 8, two nozzles 33a, 33b are connected to an under-fill resin supplier 33c. A piston is connected to the under-fill resin supplier 33c, and by moving the piston, the nozzles 33a and 33b can eject the under-fill resin at the same time. Thus, it is possible to apply the under-fill resin at plural positions at the same time with only one driving system, and it is possible to reduce the fabrication cost compared to using plural driving systems.

In addition, the nozzles 33a and 33b have different diameters, and eject different amounts of the under-fill resin. Hence, it is possible to change the amount of the under-fill resin to be applied according to the areas in which the under-fill resin is to be applied, and it is possible to appropriately adjust the amount of the under-fill resin according to sizes of the electronic parts, or the number of the electronic parts in one area to be supplied with the under-fill resin.

Each of the nozzles 33a, 33b has a taper-shaped front end with a thin end portion. Due to this, for example, even when contaminations adhere to the front end of the nozzle, it is possible to reduce deviation of resin application positions caused by attachment to the front end of the nozzle, and this improves precision of applying the under-fill resin.

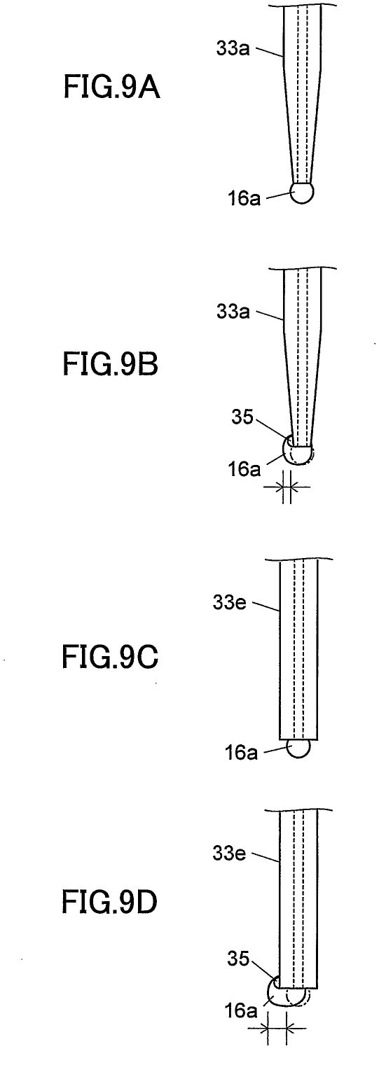

FIG. 9A through FIG. 9D are schematic views for illustrating operation of the nozzle 33a of the present invention in comparison with a nozzle 33e in the related art.

First, as shown in FIG. 9C and FIG. 9D, the nozzle 33e has a front end of uniform diameter. In this case, for example, when contaminations or other attachments 35 adhere to the front end of the nozzle 33e (FIG. D), the droplet of the under-fill resin 16a, which is ejected from the nozzle 33e, largely shifts to the side of the attachment 35.

In contrast, since the nozzle 33a has a taper-shaped front end with a thin end portion, even when the attachment 35 adheres to the front end of the nozzle 33a, the shift of the droplet of the under-fill resin 16a is small compared to the nozzle 33e as shown in FIG. 9A and FIG. 9B. Therefore, this improves the precision of applying the under-fill resin.

In the above, it is described that the under-fill resin 16a is applied at two positions, but the present embodiment is not limited to this. For example, three or more nozzles may be used to apply the under-fill resin 16a at three or more positions at the same time.

In the above, it is described that the nozzles have different diameters from each other, and eject different amounts of the under-fill resin, but the present embodiment is not limited to this. For example, the nozzles may have the same diameters, and eject the same amount of the under-fill resin.

In the above, it is described that each of the nozzles has a taper-shaped front end, but the present embodiment is not limited to this. For example, nozzles having a front end of uniform diameter may be used.

In the above, it is described that one nozzle 33a is used to apply the under-fill resin 16a to cover the protection IC chip 12 and the electronic parts 15, but the present embodiment is not limited to this. For example, the nozzles can be provided for each electronic part, or one nozzle can be used to apply the under-fill resin for three or more electronic parts.

In the above, it is described that the under-fill resin 16a fills in the space below and the space surrounding the protection IC chip 12, the field effect transistor chip 14, and the electronic parts 15, but the present embodiment is not limited to this. For example, the under-fill resin can be applied on the upper surface of the electronic parts so that the under-fill resin covers the electronic parts and form taper-shaped structures on the side surfaces of the electronic parts.

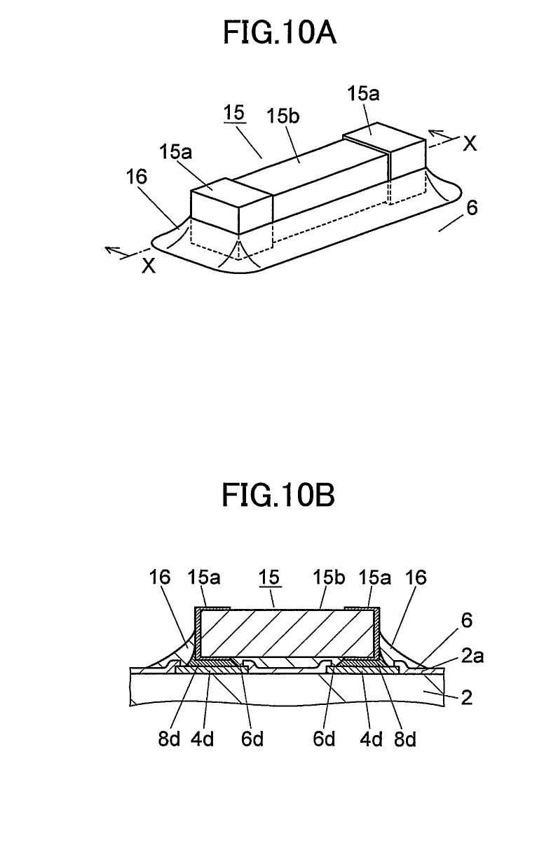

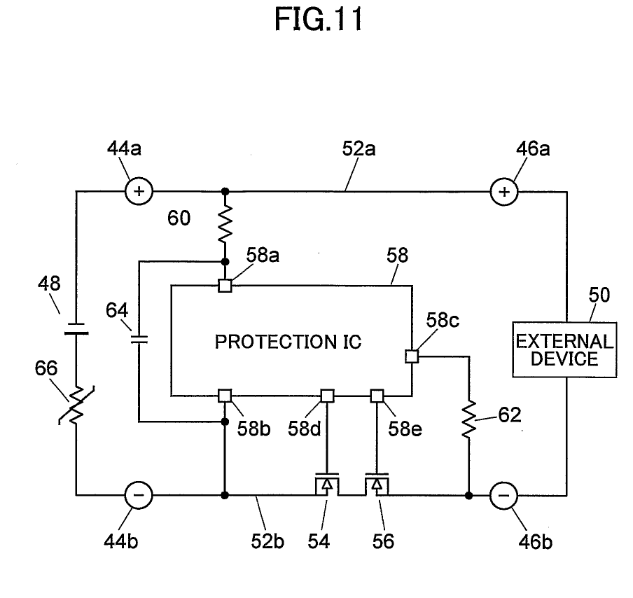

FIG. 10A is a perspective view of a taper-shaped insulating resin structure near an electronic part 15.

FIG. 10B is a cross-sectional view of the electronic part 15 taken along an XX line in FIG. 10A.

Note that in FIG. 10A, the sealing resin is not illustrated.

In the following, the same reference numbers are assigned to the same elements as those shown in FIG. 1A through FIG. 1C and FIG. 2A through FIG. 2C, and overlapping descriptions are omitted.

As shown in FIG. 10A and FIG. 10B, the electronic part electrodes 4d are formed on the surface 2a of the circuit board 2. In addition, on the surface 2a of the circuit board 2, the insulating material layer 6 is formed, and on the insulating material layer 6, the openings 6d are formed in correspondence to the electronic part electrodes 4d.

In the area where the electronic part electrodes 4d are formed, the electronic part 15 is mounted. For example, the electronic part 15 has a main body 15b of a nearly rectangular parallelepiped shape and electrodes 15a at the two ends of the main body 15b. For example, the electronic part 15 may be a thermistor element (such as a PTC element), a resistor, or a condenser. Electrodes 15a of the electronic part 15 are connected with the electronic part electrodes 4d through solder 8d in the openings 6d; thereby, the electronic part 15 is mounted on the circuit board 2.

Taper-shaped structures, which are formed by the under-fill resin 16, are formed between the electronic parts 15 and the insulating material layer 6, and in the area around the electronic parts 15. The sealing resin 18 is disposed on the insulating material layer 6 to cover the electronic parts 15 and the under-fill resin 16.

Due to the under-fill resin 16, it is possible to prevent air bubbles from entering into the sealing resin 18 near the electronic parts 15, prevent the outer appearance of the device from being influenced, and prevent degradation of reliability of the device caused by growth of the air bubbles and generation of voids when being heated.

In FIG. 1A through FIG. 1C and FIG. 2A through FIG. 2C, it is shown that the electrodes 15a are formed on one side of the main body of the electronic part 15, but as shown in FIG. 10A and FIG. 10B, the taper-shaped structures can also formed on the electronic part 15 having the electrodes 15a at the two ends of the main body 15b. Furthermore, besides the electronic parts shown in FIG. 1A through FIG. 1C, FIG. 2A through FIG. 2C, and FIG. 10A and FIG. 10B, the taper-shaped structures can also be formed on any other electronic parts mounted on a circuit board and having different structures.

In the above, the present invention is implemented to be a protection circuit module of a secondary battery, but the present invention is not limited to this embodiment; the present invention is applicable to any other device having plural electronic parts mounted on a circuit board.

While the present invention is described above with reference to specific embodiments chosen for purpose of illustration, it should be apparent that the invention is not limited to these embodiments, but numerous modifications could be made thereto by those skilled in the art without departing from the basic concept and scope of the invention.

This patent application is based on Japanese Priority Patent Applications No. 2005-194605 filed on Jul. 4, 2005, the entire contents of which are hereby incorporated by reference.

1. A method of fabricating a device including a plurality of electronic parts mounted on a circuit board with mounting areas for mounting the electronic parts being covered by a sealing resin, said method comprising the steps of, before applying the sealing resin:
applying an under-fill resin near two or more electronic parts with a plurality of nozzles at the same time; and
hardening the under-fill resin to form a taper-shaped structure around the two or more electronic parts.

2. The method as claimed in claim 1, wherein the nozzles are connected to a same under-fill resin supplier.

3. The method as claimed in claim 1, wherein the nozzles have two or more different diameters.

4. The method as claimed in claim 1, wherein each of the nozzles has a taper-shaped front end with a thin end portion.

5. The method as claimed in claim 1, wherein each of the electronic parts covered by the sealing resin is enclosed by one said taper-shaped structure.

6. A device, comprising:
a circuit board;
a plurality of electronic parts mounted on the circuit board, mounting areas for mounting the electronic parts being covered by a sealing resin; and
an under-fill resin taper-shaped structure around each of the electronic parts.

7. A secondary battery protection circuit module, comprising:
a circuit board;
a plurality of electronic parts mounted on the circuit board, mounting areas for mounting the electronic parts being covered by a sealing resin;
an under-fill resin taper-shaped structure around each of the electronic parts;
one or more of the electronic part mounting areas on one surface of the circuit board;
one or more semiconductor part mounting areas on the one surface of the circuit board for mounting one or more semiconductor parts, the semiconductor part being an electronic part having a plurality of external connection terminals arranged in the same plane;
a plurality of battery side external terminals on the one surface of the circuit board; and
a plurality of load side external terminals on another surface of the circuit board;
wherein
the semiconductor part is a bare chip and is mounted on the one surface of the circuit board in a face-down manner.

8. A battery package, comprising:
a secondary battery protection circuit module;
a secondary battery;
a connection member that electrically connects the secondary battery protection circuit module and the secondary battery; and
a housing that accommodates the secondary battery and the connection member;
wherein
the secondary battery protection circuit module includes
a circuit board;
a plurality of electronic parts mounted on the circuit board, mounting areas for mounting the electronic parts being covered by a sealing resin;
an under-fill resin taper-shaped structure around each of the electronic parts;
one or more electronic part mounting areas on one surface of the circuit board;
one or more semiconductor part mounting areas on the one surface of the circuit board for mounting one or more semiconductor parts, the semiconductor part being an electronic part having a plurality of external connection terminals arranged in the same plane;
a plurality of battery side external terminals on the one surface of the circuit board; and
a plurality of load side external terminals on another surface of the circuit board;
wherein
the semiconductor part is a bare chip and is mounted on the one surface of the circuit board in a face-down manner.
